(19) United States
(12) Patent Application Publication
(10) Pub. No.: US 2025/0180615 A1
(43) Pub. Date: Jun. 5, 2025

(54) CIRCUIT AND METHOD FOR MEASURING AND TUNING QUALITY FACTOR OF RESONATOR-BASED LOOP FILTER IN DELTA-SIGMA ANALOG-TO-DIGITAL CONVERTER

(71) Applicant: MEDIATEK INC., Hsinchu City (TW)

(72) Inventors: Yunzhi Dong, San Jose, CA (US); Gerhard Mitteregger, San Jose, CA (US); Ayman Shabra, San Jose, CA (US); Stacy Ho, San Jose, CA (US)

(73) Assignee: MEDIATEK INC., Hsinchu City (TW)

(21) Appl. No.: 18/967,583

(22) Filed: Dec. 3, 2024

Related U.S. Application Data
(60) Provisional application No. 63/605,625, filed on Dec. 4, 2023.

(51) Int. Cl. G01R 27/26; H03M 3/00

(52) U.S. Cl. CPC G01R 27/2688; H03M 3/378; H03M 3/402

(57) ABSTRACT

A measuring circuit includes a dither tone generator circuit and a digital signal processing circuit. The dither tone generator circuit generates a dither tone, and injects the dither tone to a delta-sigma analog-to-digital converter that is offline. The digital signal processing circuit processes a digital output of the delta-sigma analog-to-digital converter with the dither tone injected, to generate a Q-factor measurement result of a resonator-based loop filter included in the delta-sigma analog-to-digital converter.

### CROSS REFERENCE TO RELATED APPLICATIONS

This application claims the benefit of U.S. Provisional Application No. 63/605,625, filed on Dec. 4, 2023. The content of the application is incorporated herein by reference.

### BACKGROUND

The present invention relates to an analog-to-digital converter design, and more particularly, to a circuit and method for measuring and tuning quality factor of a resonator-based loop filter included in a delta-sigma analog-to-digital converter.

Continuous-time (CT) delta-sigma (DS) analog-to-digital converters (ADCs) are widely used in wireless transceiver. Loop filter (LF) becomes a critical component in the implementation of high resolution, wide bandwidth CTDS ADC because it determines loop stability and defines quantization noise-shaping behavior of the DS modulator. Taking band-pass CTDS ADCs for example, they use resonator-based loop filter along with accurate feedback digital-to-analog converters (DACs) to shape quantization noise of the quantizer in the desired band at a chosen carrier frequency. At the same oversampling ratio (OSR), the ADC's signal-to-quantization-noise ratio (SQNR) performance can be improved by making noise transfer function (NTF) notches more aggressive, which requires high Q-factor resonator(s) inside the resonator-based loop filter. However, a Q-factor of a resonator-based loop filter may be degraded due to various factors. Considering a case where an active resistor-capacitor (RC) resonator is used by a loop filter, a Q-factor of the active-RC resonator may be degraded due to limited amplifier gain bandwidth, non-zero amplifier output impedance, non-zero amplifier phase shift, and series losses in passive devices such as passive integration capacitors. Thus, there is a need for an innovative design for measuring and tuning Q-factor of resonators inside DS ADCs.

### SUMMARY

One of the objectives of the claimed invention is to provide a circuit and method for measuring and tuning a Q-factor of a resonator-based loop filter included in a DS ADC.

According to a first aspect of the present invention, an exemplary measuring circuit for measuring a Q-factor of a resonator-based loop filter included in a DS ADC is disclosed. The exemplary measuring circuit includes a dither tone generator circuit and a digital signal processing circuit. The dither tone generator circuit is configured to generate a dither tone, and inject the dither tone to the DS ADC that is offline. The digital signal processing circuit is configured to process a digital output of the DS ADC with the dither tone injected, to generate a Q-factor measurement result of the resonator-based loop filter.

According to a second aspect of the present invention, an exemplary tuning system for tuning a Q-factor of a resonator-based loop filter included in a DS ADC is disclosed. The exemplary tuning system includes a measuring circuit and a control circuit. The measuring circuit includes a dither tone generator circuit and a digital signal processing circuit. The dither tone generator circuit is configured to generate a dither tone, and inject the dither tone to the DS ADC that is offline. The digital signal processing circuit is configured to process a digital output of the DS ADC with the dither tone injected, to generate a Q-factor measurement result of the resonator-based loop filter. The control circuit is configured to adjust Q-factor compensation of the resonator-based loop filter according to the Q-factor measurement result.

According to a third aspect of the present invention, an exemplary method for measuring a Q-factor of a resonator-based loop filter included in a DS ADC is disclosed. The exemplary method includes: generating a dither tone and injecting the dither tone to the DS ADC that is offline; and processing a digital output of the DS ADC with the dither tone injected, to generate a Q-factor measurement result of the resonator-based loop filter.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a first tuning system for tuning a Q-factor of a resonator-based loop filter included in a delta-sigma analog-to-digital converter according to an embodiment of the present invention.

FIG. 2 is a flowchart illustrating a method of measuring and tuning a Q-factor of a resonator-based loop filter included in a delta-sigma analog-to-digital converter according to an embodiment of the present invention.

FIG. 3 is a diagram illustrating a high-Q NTF response and a low-Q NTF response achieved under different Q-factors of the resonator-based loop filter included in the continuous-time delta-sigma analog-to-digital converter shown in FIG. 1 according to an embodiment of the present invention.

FIG. 4 is a diagram illustrating measurement results of different tone frequencies obtained by the power estimation circuit shown in FIG. 1 according to an embodiment of the present invention.

FIG. 5 is a diagram illustrating a second tuning system for tuning a Q-factor of a resonator-based loop filter included in a delta-sigma analog-to-digital converter according to an embodiment of the present invention.

FIG. 6 is a diagram illustrating a third tuning system for tuning a Q-factor of a resonator-based loop filter included in a delta-sigma analog-to-digital converter according to an embodiment of the present invention.

FIG. 7 is a diagram illustrating a digital signal processing circuit used for processing a digital output of a low-pass analog-to-digital according to an embodiment of the present invention.

FIG. 8 is a diagram illustrating a digital signal processing circuit used for processing a digital output of an analog-to-digital converter (e.g., a high-pass analog-to-digital converter or a low-pass analog-to-digital converter) according to an embodiment of the present invention.

### DETAILED DESCRIPTION

Certain terms are used throughout the following description and claims, which refer to particular components. As one skilled in the art will appreciate, electronic equipment manufacturers may refer to a component by different names. This document does not intend to distinguish between components that differ in name but not in function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is coupled to another device, that connection may be through a direct electrical connection, or through an indirect electrical connection via other devices and connections.

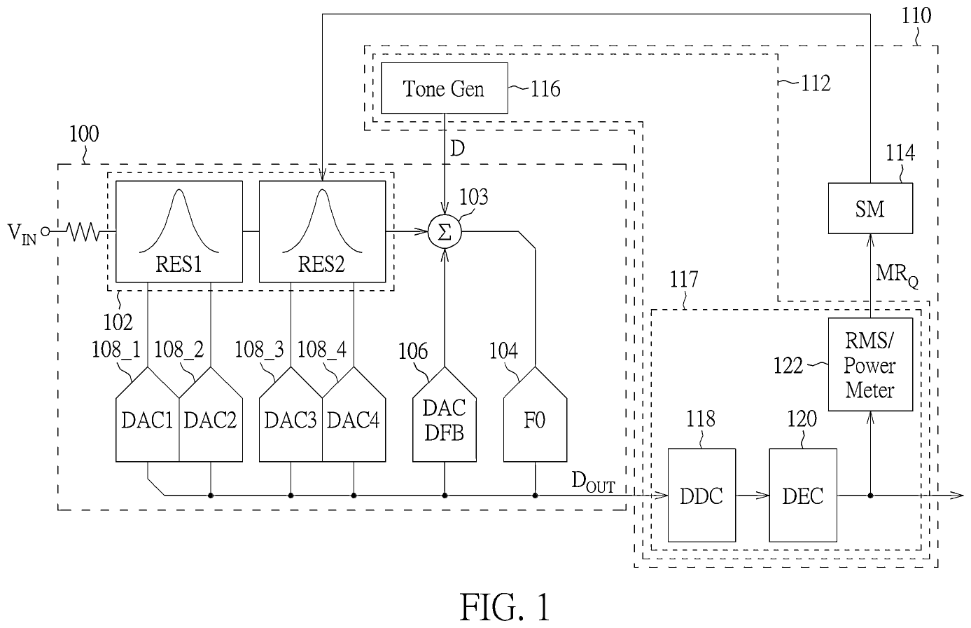

FIG. 1 is a diagram illustrating a first tuning system for tuning a Q-factor of a resonator-based loop filter included in a DS ADC according to an embodiment of the present invention. In this embodiment, a CTDS ADC 100 includes a resonator-based loop filter 102, a summation circuit 103, a quantizer (labeled by “F0”) 104, a direct feedback DAC (labeled by “DAC DFB”) 106, and a plurality of high-speed feedback DACs (labeled by “DAC1”, “DAC2”, “DAC3”, “DAC4”) 108_1, 108_2, 108_3, 108_4. For example, the CTDS ADC 100 may be a 4^{th}-order band-pass CTDS ADC, the resonator-based loop filter 102 may include two resonators (e.g., active-RC resonators) RES1 and RES2, and the quantizer 104 may be a Flash ADC. Since the present invention is focused on the tuning system 110 that supports the proposed Q-factor measurement and tuning scheme and a skilled artisan can readily understand principles of the CTDS ADC 100, further description of the CTDS ADC 100 is omitted here for brevity.

In this embodiment, the tuning system 110 includes a measuring circuit 112 and a control circuit (labeled by “SM”) 114. The control circuit 114 is responsible for Q-factor tuning control of the resonator-based loop filter 102. For example, the control circuit 114 may be a state machine (SM) implemented by firmware running on a microprocessor. In this embodiment, Q-factor compensation of the resonator-based loop filter 102 can be adjusted through tuning analog circuits (actuators) included in the resonator RES2 of the resonator-based loop filter 102.

The measuring circuit 112 is responsible for Q-factor measurement, and includes a dither tone generator circuit (labeled by “Tone Gen”) 116 and a digital signal processing circuit 117. The dither tone generator circuit 116 is configured to generate a dither tone D, and inject the dither tone D to the CTDS ADC 100 during a period in which the CTDS ADC 100 is offline (i.e., an analog input VIN is not present at an input node of CTDS ADC 100). In this embodiment, the dither tone D is an analog tone that is injected to the summation circuit 103 located at an input node of the quantizer (e.g., Flash ADC) 104. For example, the dither tone D may be a square wave or a sine wave, depending upon actual design considerations.

The digital signal processing circuit 117 is configured to process a digital output D_{OUT} of the CTDS ADC 100 with the dither tone D injected, to generate a Q-factor measurement result MR_{Q} of the resonator-based loop filter 102. In this embodiment, the digital signal processing circuit 117 may include a digital down-conversion circuit (labeled by “DDC”) 118, a decimation filter (labeled by “DEC”) 120, and a power estimation circuit (labeled by “RMS/Power Meter”) 122. The digital down-conversion circuit 118 and decimation filter 120 used by a receiver (RX) ADC system may be re-used by the tuning system 110. Since the CTDS ADC 100 is a band-pass ADC, the digital down-conversion circuit 118 may be used to shift the bandwidth of interest to baseband and discard the rest of data, allowing more intensive processing to be performed on the signal of interest. The complex signal output (I+Q) of the digital down-conversion circuit 118 is processed by the decimation filter 120. The decimation filter 120 is used to implement down-sampling and filtering. The power estimation circuit 122 is used to observe root mean square (RMS) power of a decimated complex signal over a defined bandwidth (e.g., BW=80 MHz) near the dither tone frequency (which is achieved through digital down-conversion and decimation filtering).

The control circuit (e.g., state machine) 114 is configured to adjust Q-factor compensation of the resonator-based loop filter 102 according to the Q-factor measurement result MR_{Q}. In this embodiment, the dither tone generator circuit 116 may inject the dither tone D from a start tone frequency (e.g., a band-center frequency f0) to a stop tone frequency (e.g., a band-edge frequency fmax or fmin) for a frequency sweep test. Hence, the Q measurement result MR_{Q} may include a plurality of measurement results (e.g., RMS power values) obtained for a plurality of different tone frequencies of the dither tone D, respectively. The control circuit 114 adjusts the Q-factor compensation of the resonator-based loop filter 102 by comparing a local minimum among the plurality of measurement results and a measurement result obtained for a reference frequency (e.g., band-center frequency f0). When a difference between the measurement result of the reference frequency (e.g., band-center frequency f0) and the local minimum does not exceed a pre-defined threshold, the control circuit 114 increases strength of the Q-factor compensation of the resonator-based loop filter 102, and then the digital signal processing circuit 117 processes the digital output D_{OUT} of the CTDS ADC 100 with the dither tone D injected, to generate another Q-factor measurement result MR_{Q} of the resonator-based loop filter 102. The control circuit 114 does not stop adjusting the Q-factor compensation of the resonator-based loop filter 102 until the difference between the measurement result of the reference frequency (e.g., band-center frequency f0) and the local minimum exceeds the pre-defined threshold.

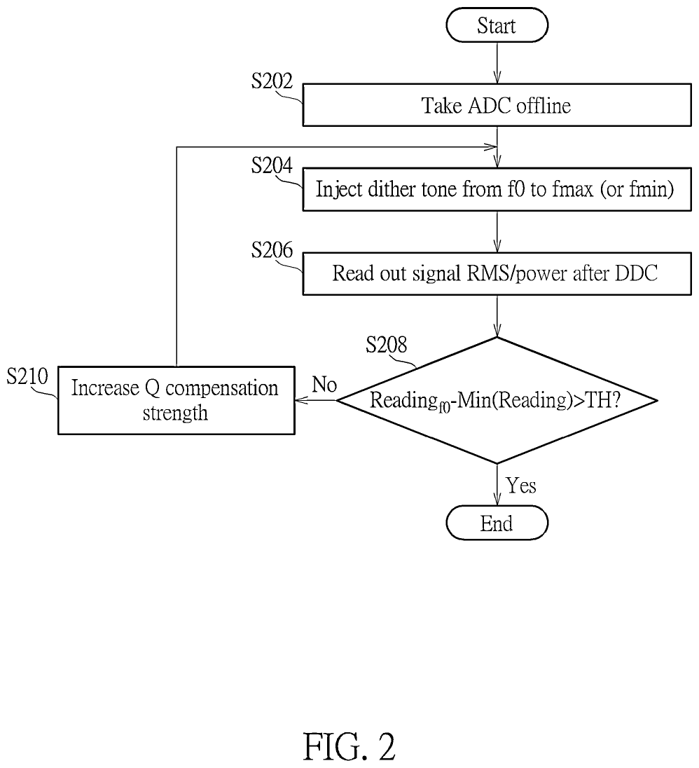

FIG. 2 is a flowchart illustrating a method of measuring and tuning a Q-factor of a resonator-based loop filter included in a DS ADC according to an embodiment of the present invention. Provided that the result is substantially the same, the steps are not required to be executed in the exact order shown in FIG. 2. The Q-factor of the resonator-based loop filter 102 included in the CTDS ADC (e.g., band-pass CTDC ADC) 100 is tuned under a condition that the CTDS ADC 100 is offline (step S202). In other words, there is no voltage input VIN fed into an input node of the DS ADC 100 during a period in which the proposed Q-factor measurement and tuning scheme is enabled.

At step S204, the dither tone D generated from the dither tone generator circuit 116 is injected to the summation circuit 103 for a frequency sweep test of a plurality of different tone frequencies within the band of interest. For example, the dither tone generator circuit 116 injects the dither tone D from a start tone frequency (e.g., band-center frequency f0) to a stop tone frequency (e.g., band-edge frequency fmax or fmin). At step S206, the control circuit 114 reads one measurement result (e.g., RMS power over a defined BW near the tone frequency) from the digital signal processing circuit 117 for each of the different tone frequencies of the dither tone D. At step S208, the control circuit 114 examines the measurement results (e.g., RMS power values) to detect existence of a high-Q NTF notch. For example, the resonator-based loop filter 102 with a high Q-factor means a high-Q NTF notch larger than 10 dB. Hence, the control circuit 114 finds a local minimum Min (Reading) among the plurality of measurement results, and compares the local minimum Min (Reading) and a measurement result (e.g., Reading_{f0}) obtained for the reference frequency, where the reference frequency (e.g., band-center frequency f0) may be the start tone frequency of the dither tone D during the frequency sweep test.

When a difference between the measurement result Reading_{f0} and the local minimum Min (Reading) does not exceed a pre-defined threshold TH (e.g., TH=10 dB), the control circuit 114 increases strength of the Q-factor compensation of the resonator-based loop filter 112 for Q-factor enhancement (steps S208 and S210). Next, the Q-factor measurement is performed again to obtain another Q-factor measurement MR_{Q} under a condition that Q-factor of the resonator-based loop filter 112 is tuned by step S210. Hence, the dither tone D is injected to the summation circuit 103 again for a frequency sweep test (step S204), and the digital signal processing circuit 117 processes the digital output D_{OUT} of the CTDS ADC 100 with the dither tone D injected, to generate another Q-factor measurement result MR_{Q} of the resonator-based loop filter 112. The control circuit 114 checks the difference between the measurement result Reading_{f0} and the local minimum Min (Reading) again, to determine whether to increase strength of the Q-factor compensation of the resonator-based loop filter 112. The control circuit 114 does not stop adjusting the Q-factor compensation of the resonator-based loop filter 112 until the difference between the measurement result Reading_{f0} and the local minimum Min (Reading) exceeds the pre-defined threshold TH. A good Q-factor should result in a difference exceeding the pre-defined threshold TH (e.g., TH=10 dB). Hence, when the difference is found larger than the pre-defined threshold TH (e.g., TH=10 dB) during the latest Q-factor tuning iteration, it is determined that the resonator-based loop filter 112 has a good Q-factor.

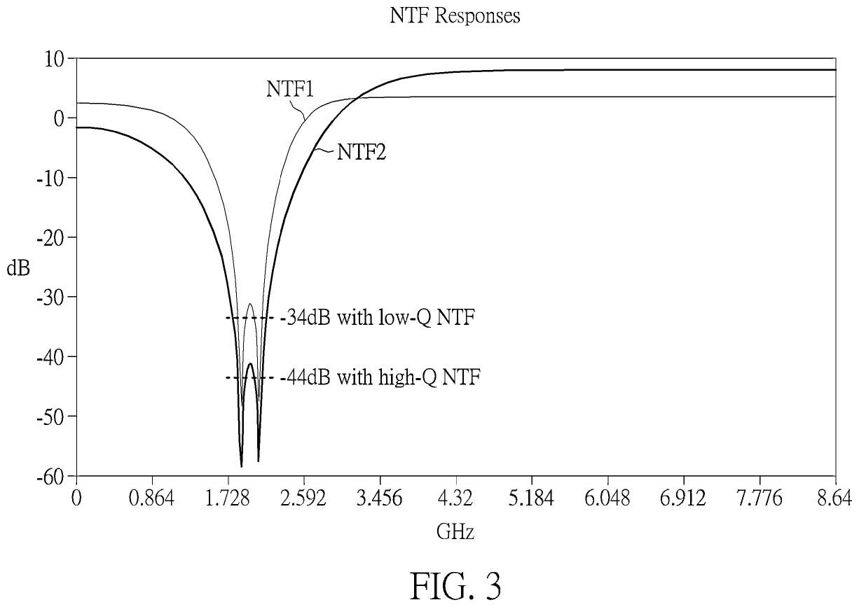

FIG. 3 is a diagram illustrating a high-Q NTF response and a low-Q NTF response achieved under different Q-factors of the resonator-based loop filter 102 included in the CTDS ADC 100 according to an embodiment of the present invention. Suppose that the resonator-based loop filter 102 is a band-pass filter, and a band-center frequency f0 of the signal band with BW=320 MHz is 1.98 GHz. When the resonator-based loop filter 102 has a low Q-factor, the NTF response NTF1 with low-Q notches has lower noise attenuation in the signal band. Since the low-Q resonator-based loop filter 102 fails to meet the criterion checked at step S208, the control circuit 114 increases strength of Q-factor the compensation of the resonator-based loop filter 112 for Q-factor enhancement. When the criterion checked at step S208 is met, the resonator-based loop filter 102 is properly tuned to have a high Q-factor, and NTF response NTF2 with high-Q notches has higher noise attenuation in the signal band and thus better SQNR.

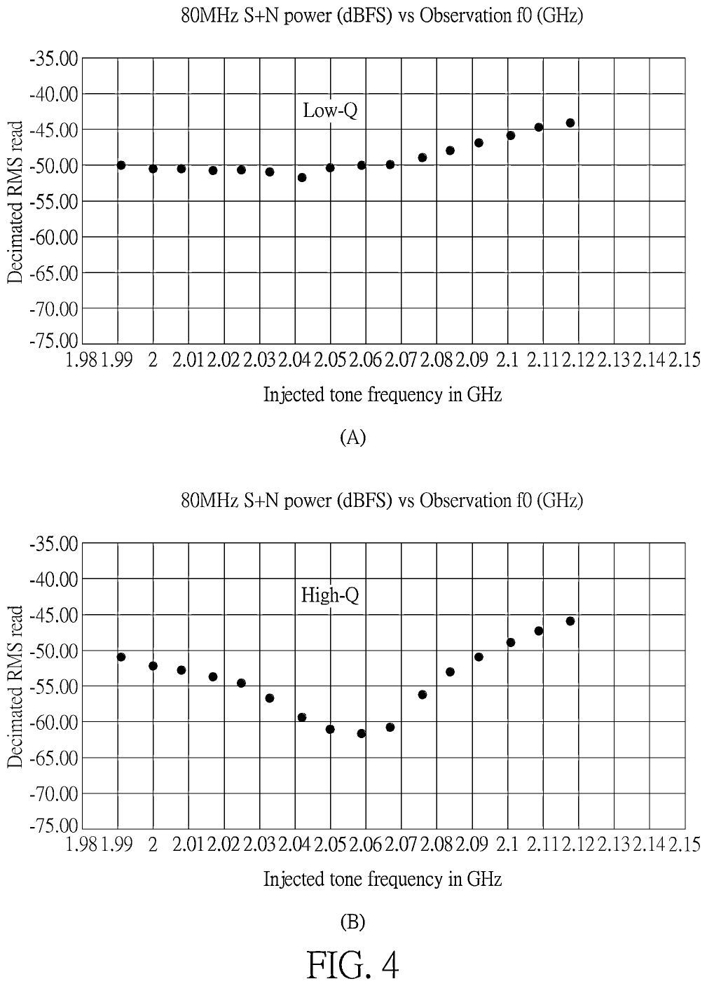

FIG. 4 is a diagram illustrating measurement results (e.g., RMS power values) of different tone frequencies obtained by the power estimation circuit 122 according to an embodiment of the present invention. When the resonator-based loop filter 102 has a low Q-factor, it is not easy to see the notch, and a difference between a measurement result at a band-center frequency (e.g., 2 GHZ) and a local minimum is smaller than 1 dB, as illustrated in sub-diagram (A) of FIG. 4. When the resonator-based loop filter 102 has a high Q-factor, it is clearly to see the notch at 2.06 GHZ, and a difference between a measurement result at a band-center frequency (e.g., 2 GHZ) and the local minimum at this notch frequency is larger than 10 dB, as illustrated in sub-diagram (B) of FIG. 4. When the Q-factor compensation of the resonator-based loop filter 102 is properly tuned to make a difference between a measurement result at a band-center frequency and a local minimum of the measurement results exceed a pre-defined threshold (e.g., 10 dB), it is determined that the resonator-based loop filter 102 can realize these high-Q NTF notches for better SQNR.

Regarding the embodiment shown in FIG. 1, the dither tone D is an analog tone that is injected to an input node of the quantizer 104. However, this is for illustrative purposes only, and is not meant to be a limitation of the present invention. In practice, any means capable of adding a dither tone to quantization noise of a quantizer in a DS ADC can be employed by the proposed Q-factor measurement and tuning scheme.

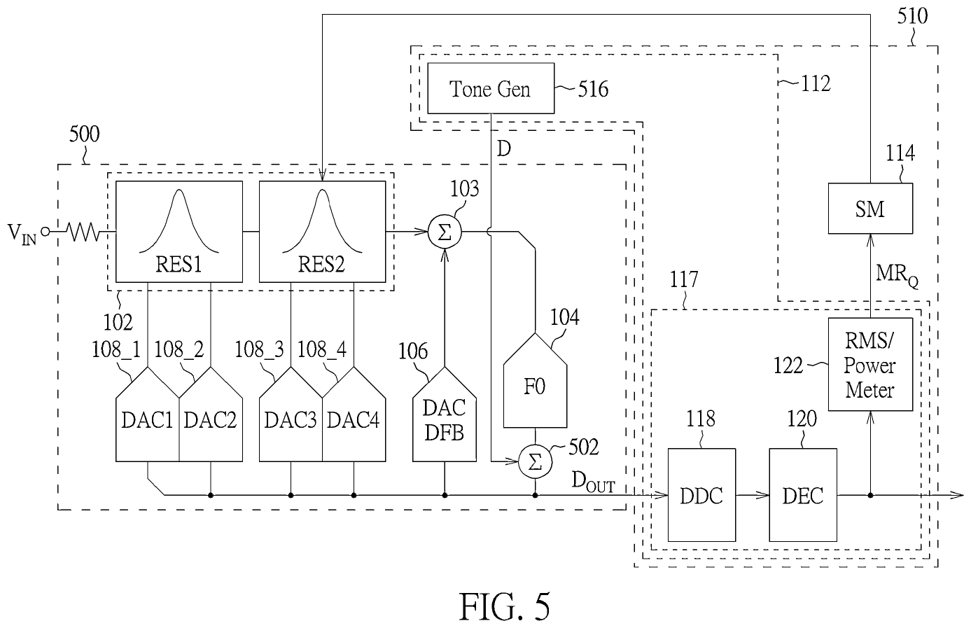

FIG. 5 is a diagram illustrating a second tuning system for tuning a Q-factor of a resonator-based loop filter included in a DS ADC according to an embodiment of the present invention. The major difference between the tuning systems 110 and 510 is that the dither tone D generated from the dither tone generator circuit 516 is a digital tone that is injected to a summation circuit 502 located at an output node of the quantizer 104 of the CTDS ADC (e.g., band-pass CTDS ADC) 500.

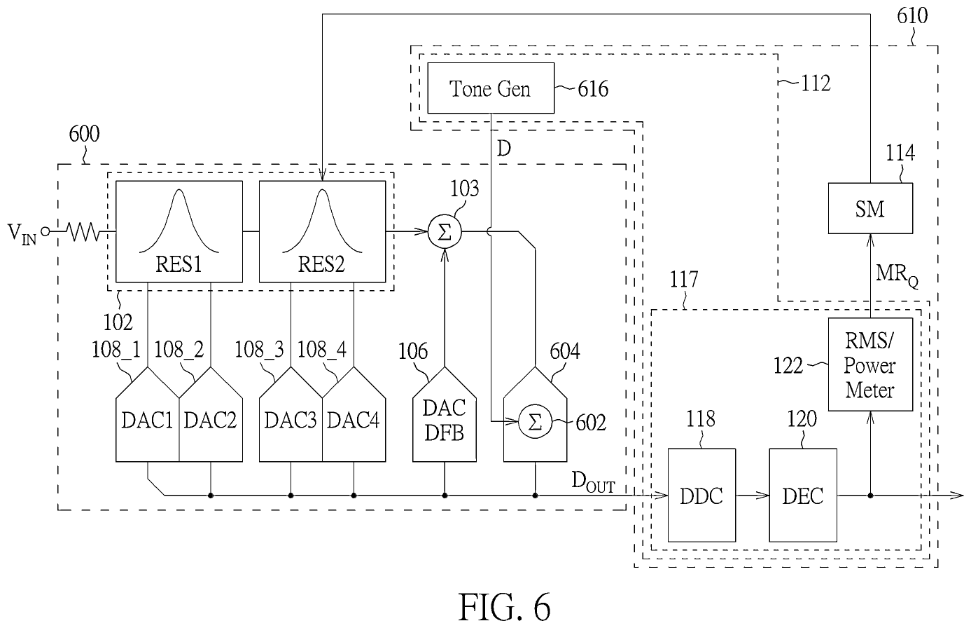

FIG. 6 is a diagram illustrating a third tuning system for tuning a Q-factor of a resonator-based loop filter included in a DS ADC according to an embodiment of the present invention. The major difference between the tuning systems 110 and 610 is that the dither tone D generated from the dither tone generator circuit 616 may be a digital tone or an analog tone that is injected to a summation circuit 602 located at an internal node of the quantizer 604 of the CTDS ADC (e.g., band-pass CTDS ADC) 600. For example, the quantizer 604 may be implemented using a Flash ADC, and the internal node may be connected between internal circuit blocks of the Flash ADC.

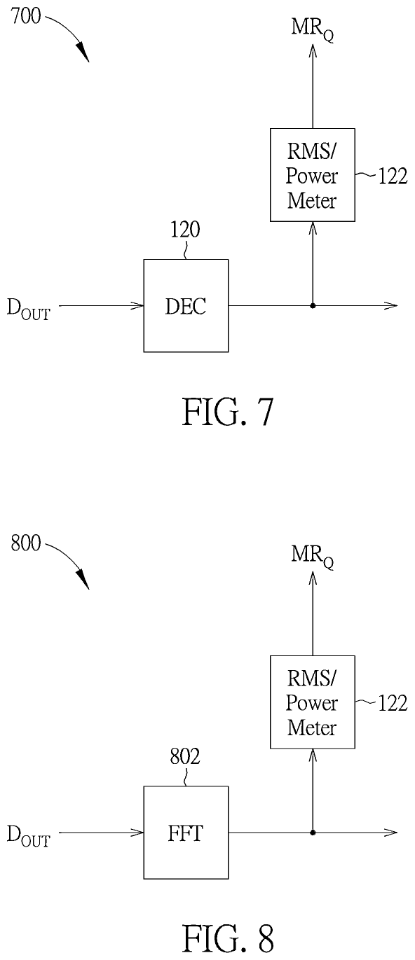

In above embodiments, the CTDS ADC 100/500/600 may be a band-pass ADC due to the resonator-based loop filter 102 being configured to act as a band-pass filter. Hence, the digital signal processing circuit 117 includes the digital down-conversion circuit 118. However, this is for illustrative purposes only, and is not meant to be a limitation of the present invention. For example, the proposed Q-factor measuring and tuning scheme can also apply to a low-pass ADC using a resonator-based loop filter that is configured to act as a low-pass filter. FIG. 7 is a diagram illustrating a digital signal processing circuit used for processing a digital output of a low-pass ADC according to an embodiment of the present invention. When the CTDS ADC 100/500/600 is modified to employ the resonator-based loop filter 102 that is configured to act as a low-pass filter, the digital signal processing circuit 117 may be replaced by the digital signal processing circuit 700. As shown in FIG. 7, there is no digital down-conversion circuit included in the digital signal processing circuit 700.

FIG. 8 is a diagram illustrating a digital signal processing circuit used for processing a digital output of an ADC (e.g., a high-pass ADC or a low-pass ADC) according to an embodiment of the present invention. The digital signal processing circuit 117 may be replaced by the digital signal processing circuit 800. The digital signal processing 800 circuit includes a fast Fourier transform circuit (labeled by “FFT”) 802. The same objective of obtaining the Q-factor measurement result MR_{Q} of the resonator-based loop filter 102 can be achieved by FFT analysis of the digital signal processing circuit 800.

It should be noted that the proposed Q-factor measurement and tuning scheme may be merged with other techniques regarding CTDS ADC NTF notch frequency tuning. For example, when step S208 determines that a difference between a measurement result at a reference frequency and a local minimum at a specific tone frequency exceeds a pre-defined threshold, the specific tone frequency at which the local minimum occurs may be treated as a coarse NTF notch frequency for the following NTF notch frequency tuning procedure.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A measuring circuit for measuring a quality (Q) factor of a resonator-based loop filter included in a delta-sigma (DS) analog-to-digital converter (ADC), comprising:
a dither tone generator circuit, configured to generate a dither tone, and inject the dither tone to the DS ADC that is offline; and
a digital signal processing circuit, configured to process a digital output of the DS ADC with the dither tone injected, to generate a Q-factor measurement result of the resonator-based loop filter.

2. The measuring circuit of claim 1, wherein the DS ADC is a continuous-time DS ADC.

3. The measuring circuit of claim 1, wherein the DS ADC is a band-pass ADC.

4. The measuring circuit of claim 3, wherein the digital signal processing circuit comprises a digital down-conversion (DDC) circuit and a decimation filter.

5. The measuring circuit of claim 1, wherein the DS ADC is a low-pass ADC.

6. The measuring circuit of claim 5, wherein the digital signal processing circuit comprises a decimation filter.

7. The measuring circuit of claim 1, wherein the digital signal processing circuit comprises a fast Fourier transform (FFT) circuit.

8. The measuring circuit of claim 1, wherein the dither tone is a digital tone.

9. The measuring circuit of claim 1, wherein the dither tone is an analog tone.

10. The measuring circuit of claim 1, wherein the dither tone is injected to an input node of a quantizer included in the DS ADC.

11. The measuring circuit of claim 1, wherein the dither tone is injected to an internal node of a quantizer included in the DS ADC.

12. The measuring circuit of claim 1, wherein the dither tone is injected to an output node of a quantizer included in the DS ADC.

13. The measuring circuit of claim 1, wherein the dither tone generator circuit is configured to inject the dither tone from a start tone frequency to a stop tone frequency for a frequency sweep test; and the Q-factor measurement result comprises a plurality of measurement results obtained for a plurality of different tone frequencies of the dither tone, respectively.

14. A tuning system for tuning a quality (Q) factor of a resonator-based loop filter included in a delta-sigma (DS) analog-to-digital converter (ADC), comprising:
a measuring circuit, comprising:
a dither tone generator circuit, configured to generate a dither tone, and inject the dither tone to the DS ADC that is offline; and
a digital signal processing circuit, configured to process a digital output of the DS ADC with the dither tone injected, to generate a Q-factor measurement result of the resonator-based loop filter; and
a control circuit, configured to adjust Q-factor compensation of the resonator-based loop filter according to the Q-factor measurement result.

15. The tuning system of claim 14, wherein the dither tone generator circuit is configured to inject the dither tone from a start tone frequency to a stop tone frequency for a frequency sweep test; and the Q measurement result comprises a plurality of measurement results obtained for a plurality of different tone frequencies of the dither tone, respectively.

16. The tuning system of claim 15, wherein the control circuit is configured to adjust the Q-factor compensation of the resonator-based loop filter by comparing a local minimum among the plurality of measurement results and a measurement result obtained for a reference frequency, where the reference frequency is included in the plurality of different tone frequencies.

17. The tuning system of claim 16, wherein when a difference between the measurement result and the local minimum does not exceed a pre-defined threshold, the control circuit is configured to increase strength) of the Q-factor compensation of the resonator-based loop filter, and the digital signal processing circuit is configured to process the digital output of the DS ADC with the dither tone injected, to generate another Q-factor measurement result of the resonator-based loop filter.

18. The tuning system of claim 16, wherein the control circuit does not stop adjusting the Q-factor compensation of the resonator-based loop filter until a difference between the measurement result and the local minimum exceeds a pre-defined threshold.

19. The tuning system of claim 14, wherein the DS ADC is a band-pass continuous-time DS ADC.

20. A method for measuring a quality (Q) factor of a resonator-based loop filter included in a delta-sigma (DS) analog-to-digital converter (ADC), comprising:
generating a dither tone and injecting the dither tone to the DS ADC that is offline; and
processing a digital output of the DS ADC with the dither tone injected, to generate a Q-factor measurement result of the resonator-based loop filter.
